(19) United States
(12) Patent Application Publication
(10) Pub. No.: US 2025/0353299 A1
(43) Pub. Date: Nov. 20, 2025

(54) LIQUID DISCHARGE HEAD, LIQUID DISCHARGE DEVICE AND PIEZOELECTRIC ELEMENT

(71) Applicant: SEIKO EPSON CORPORATION, Tokyo (JP)

(72) Inventors: Motoki TAKABE, SHIOJIRI-SHI (JP); Masao NAKAYAMA, SHIOJIRI-SHI (JP); Koji OHASHI, MATSUMOTO-SHI (JP)

(21) Appl. No.: 19/205,491

(22) Filed: May 12, 2025

(30) Foreign Application Priority Data
May 15, 2024 (JP) 2024-079233

(51) Int. Cl. B41J 2/14; B41J 2/045; H10N 30/00; H10N 30/20; H10N 30/853; H10N 30/87

(52) U.S. Cl. CPC B41J 2/14233; B41J 2/04581; B41J 2/1433; H10N 30/202; H10N 30/704; H10N 30/8542; H10N 30/871; B41J 2002/14258; B41J 2002/14491

(57) ABSTRACT

A liquid discharge head includes a pressure chamber substrate provided with a plurality of pressure chambers, a vibration plate, a first electrode, a first thin film piezoelectric body, a second thin film piezoelectric body, and a second electrode, which are laminated in this order along a lamination direction, in which a content of lead contained in the liquid discharge head is 0.1% by weight or less, no other member is interposed between the first thin film piezoelectric body and the second thin film piezoelectric body, and a Young's modulus of the second thin film piezoelectric body is higher than a Young's modulus of the first thin film piezoelectric body.

The present application is based on, and claims priority from JP Application Serial Number 2024-079233, filed May 15, 2024, the disclosure of which is hereby incorporated by reference herein in its entirety.

### BACKGROUND

### 1. Technical Field

The present disclosure relates to a liquid discharge head, a liquid discharge device and a piezoelectric element.

### 2. Related Art

There is known a liquid discharge head including a pressure chamber substrate having a pressure chamber, a vibration plate that generates a pressure in the pressure chamber, and a piezoelectric actuator including a piezoelectric body provided on the vibration plate. JP-A-2011-155272 discloses a liquid discharge head including a non-lead-based thin film piezoelectric body.

However, in a non-lead-based thin film piezoelectric body, a displacement characteristic is decreased as compared to a lead-based thin film piezoelectric body. In addition, in the non-lead-based thin film piezoelectric body, a stress difference between the vibration plate and the piezoelectric body is larger than that in the lead-based thin film piezoelectric body, and there is a concern that a crack may occur. As described above, in the non-lead-based thin film piezoelectric body, there is a problem that both obtaining a sufficient displacement characteristic and suppressing the occurrence of cracks cannot be achieved.

### SUMMARY

According to a first aspect of the present disclosure, there is provided a liquid discharge head. The liquid discharge head includes a pressure chamber substrate provided with a plurality of pressure chambers, a vibration plate, a first electrode, a first thin film piezoelectric body, a second thin film piezoelectric body, and a second electrode, which are laminated in this order along a lamination direction, in which a content of lead contained in the liquid discharge head is 0.1% by weight or less, no other member is interposed between the first thin film piezoelectric body and the second thin film piezoelectric body, and a Young's modulus of the second thin film piezoelectric body is higher than a Young's modulus of the first thin film piezoelectric body.

According to a second aspect of the present disclosure, there is provided a liquid discharge device. The liquid discharge device includes the liquid discharge head according to the first aspect, and a controller that controls a discharge operation from the liquid discharge head.

### BRIEF DESCRIPTION OF THE DRAWINGS

FIG. 1 is an explanatory view illustrating a schematic configuration of a liquid discharge device according to a first embodiment.

FIG. 2 is an exploded perspective view illustrating a configuration of a liquid discharge head.

FIG. 3 is an explanatory view illustrating the configuration of the liquid discharge head in plan view.

FIG. 4 is a cross-sectional view illustrating a position IV-IV in FIG. 3.

FIG. 5 is a cross-sectional view schematically illustrating a detailed configuration of a piezoelectric element.

FIG. 6 is a cross-sectional view schematically illustrating a detailed configuration of a piezoelectric body.

FIG. 7 is a cross-sectional view schematically illustrating a detailed configuration of a piezoelectric body of a second embodiment.

### DESCRIPTION OF EMBODIMENTS

### A. First Embodiment

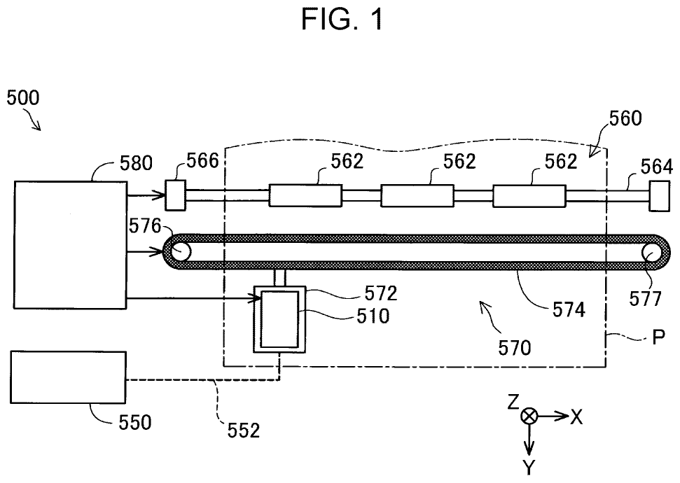

FIG. 1 is an explanatory view illustrating a schematic configuration of a liquid discharge device 500 according to a first embodiment. In the present embodiment, the liquid discharge device 500 is an ink jet printer that discharges ink as an example of a liquid onto printing paper P to form an image. The liquid discharge device 500 may use any kind of medium, such as a resin film or a cloth, as a target on which ink is to be discharged, instead of the printing paper P. X, Y, and Z illustrated in FIG. 1 and each drawing subsequent to FIG. 1 represent three spatial axes orthogonal to each other. In the present specification, directions along the axes are also referred to as an X-axis direction, a Y-axis direction, and a Z-axis direction. In specifying the direction, a positive direction is “+” and a negative direction is “−” so that positive and negative signs are used together in the direction notation, and description will be performed while a direction to which an arrow faces in each drawing is the + direction and an opposite direction thereof is the − direction. In the present embodiment, the Z-axis direction coincides with a vertical direction, a +Z direction indicates vertically downward, and a −Z direction indicates vertically upward. Further, when the positive direction and the negative direction are not limited, the three X, Y, and Z will be described as the X axis, the Y axis, and the Z axis.

The liquid discharge device 500 includes a liquid discharge head 510, an ink tank 550, a transport mechanism 560, a movement mechanism 570, and a controller 580. The liquid discharge head 510 is formed with a plurality of nozzles, discharges inks of a total of four colors, for example, black, cyan, magenta, and yellow in the +Z direction to form an image on the printing paper P. The liquid discharge head 510 is mounted on a carriage 572 and reciprocates in a main scanning direction with the movement of the carriage 572. In the present embodiment, the main scanning directions are a +X direction and a −X direction. The liquid discharge head 510 may further discharge ink of any color such as light cyan, light magenta, clear, or white, in addition to the four colors.

The ink tank 550 accommodates the ink to be discharged to the liquid discharge head 510. The ink tank 550 is coupled to the liquid discharge head 510 by a resin tube 552. The ink in the ink tank 550 is supplied to the liquid discharge head 510 via the tube 552. Instead of the ink tank 550, a bag-shaped liquid pack formed of a flexible film may be provided.

The transport mechanism 560 transports the printing paper P in a sub-scanning direction. The sub-scanning direction is a direction that intersects the X-axis direction, which is a main scanning direction, and is a +Y direction and a −Y direction in the present embodiment. The transport mechanism 560 includes a transport rod 564, on which three transport rollers 562 are mounted, and a transport motor 566 for rotatably driving the transport rod 564. When the transport motor 566 rotatably drives the transport rod 564, the printing paper P is transported in the +Y direction, which is the sub-scanning direction. The number of the transport rollers 562 is not limited to three and may be any number. In addition, a configuration, in which a plurality of transport mechanisms 560 are provided, may be provided.

The movement mechanism 570 includes the carriage 572, a transport belt 574, a movement motor 576, and a pulley 577. The carriage 572 mounts the liquid discharge head 510 in a state in which the ink can be discharged. The carriage 572 is fixed to the transport belt 574. The transport belt 574 is bridged between the movement motor 576 and the pulley 577. When the movement motor 576 is rotatably driven, the transport belt 574 reciprocates in the main scanning direction. As a result, the carriage 572 fixed to the transport belt 574 also reciprocates in the main scanning direction.

The controller 580 is configured as a microcomputer including a CPU and a storage section. The storage section is, for example, a non-volatile memory such as an EEPROM that can be erased by an electric signal, a non-volatile memory such as a One-Time-PROM and an EPROM that can be erased by ultraviolet rays, or a non-volatile memory such as a PROM that cannot be erased. The storage section stores various programs for realizing functions provided in the present embodiment. The CPU oversees the control of each section of the liquid discharge device 500 by developing and executing a program stored in the storage section. The controller 580 controls the reciprocating operation of the carriage 572 along the main scanning direction, the transport operation of the printing paper P along the sub-scanning direction, and the discharge operation of discharging the liquid from the liquid discharge head 510.

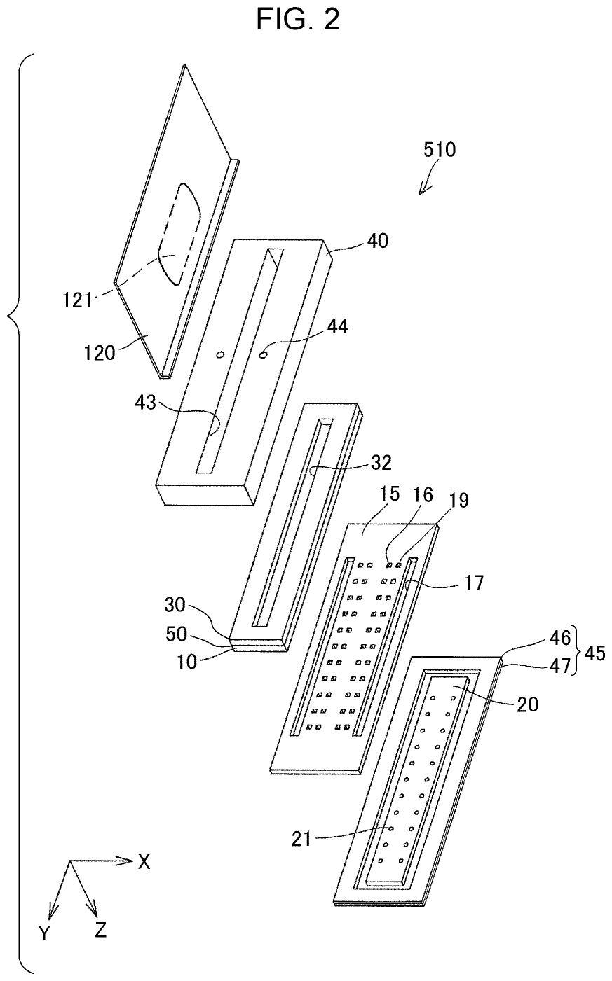

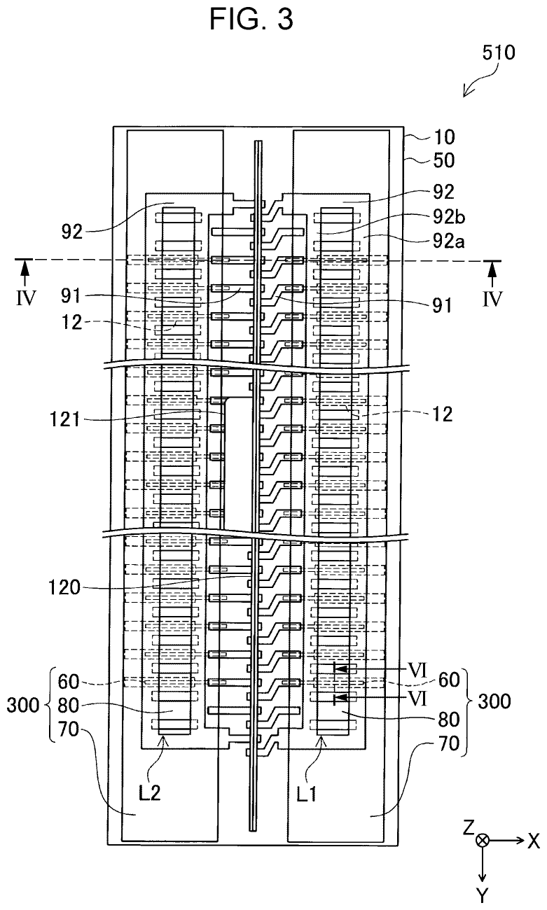

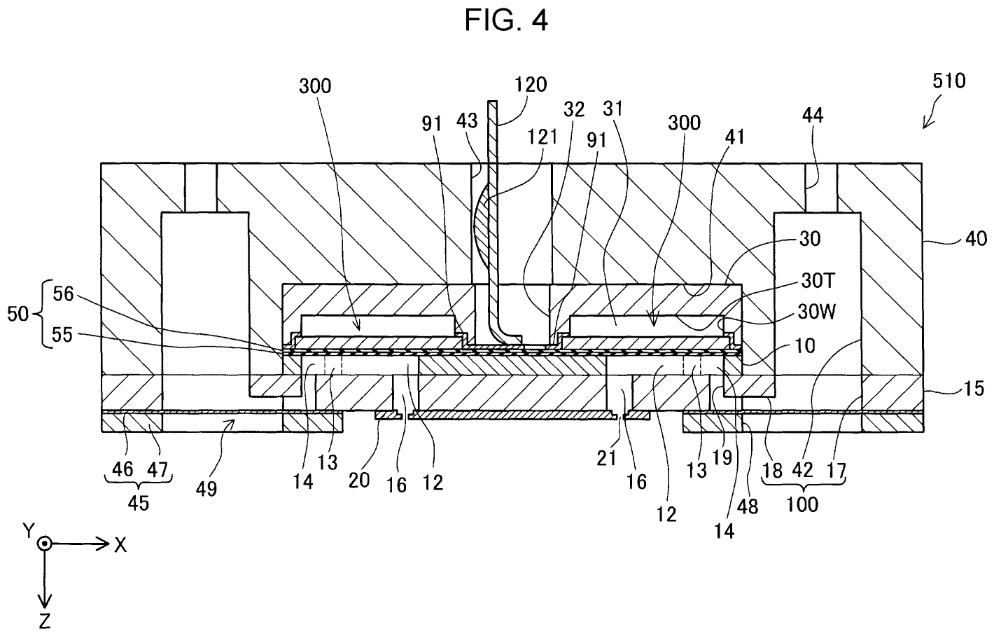

A detailed configuration of the liquid discharge head 510 will be described with reference to FIGS. 2 to 4. FIG. 2 is an exploded perspective view illustrating the configuration of the liquid discharge head 510. FIG. 3 is an explanatory view illustrating the configuration of the liquid discharge head 510 in plan view. In the present disclosure, the “plan view” means a state in which an object is viewed along a lamination direction to be described later. FIG. 3 illustrates the configuration around a pressure chamber substrate 10 and a vibration plate 50 in the liquid discharge head 510, and in order to facilitate understanding of the technique, illustration of a protective layer 83, a sealing substrate 30, a case member 40, or the like is omitted. FIG. 4 is a cross-sectional view illustrating a position IV-IV of FIG. 3.

The liquid discharge head 510 includes the pressure chamber substrate 10, a communication plate 15, a nozzle plate 20, a compliance substrate 45, the vibration plate 50, the sealing substrate 30, the case member 40, a wiring substrate 120, which are illustrated in FIG. 2, and a piezoelectric element 300 illustrated in FIG. 3. The liquid discharge head 510 is provided by laminating these laminated members. In the present disclosure, a direction in which the laminated members forming the liquid discharge head 510 are laminated is also referred to as a “lamination direction”. In the present embodiment, the lamination direction coincides with the Z-axis direction. In the present disclosure, the +Z direction side with respect to a predetermined reference position is also referred to as “one side of the lamination direction” or “lower side”, and the −Z direction side with respect to a predetermined reference position is also referred to as “the other side of the lamination direction” or “upper side”.

The pressure chamber substrate 10 is formed by using, for example, a silicon substrate, a glass substrate, an SOI substrate, various ceramic substrates, or the like. As illustrated in FIG. 3, a plurality of pressure chambers 12 are provided on the pressure chamber substrate 10. An ink flow path provided on the pressure chamber substrate 10, such as the pressure chamber 12, is formed by performing anisotropic etching on the pressure chamber substrate 10 from the surface on the +Z direction side. The pressure chamber 12 is provided to extend along the X-axis direction. Specifically, the pressure chamber 12 is formed in a substantially rectangular shape in which the length in the X-axis direction is longer than the length in the Y-axis direction in plan view. The shape of the pressure chamber 12 is not limited to the rectangular shape, and may be a parallelogram shape, a polygonal shape, an oval shape, or the like. The oval shape means a shape in which both end portions in a longitudinal direction are semicircular based on a rectangular shape, and includes a rounded rectangular shape, an elliptical shape, an egg shape, or the like. In the present disclosure, the X-axis direction is also referred to as an “extending direction”.

As illustrated in FIG. 3, the plurality of pressure chambers 12 are arranged along a direction intersecting the extending direction on the pressure chamber substrate 10. In plan view of the liquid discharge head 510 along the lamination direction, a direction in which the plurality of pressure chambers 12 are arranged is also referred to as an “arrangement direction”. That is, the arrangement direction is a direction intersecting the extending direction and the lamination direction. In the present embodiment, the plurality of pressure chambers 12 are each arranged in two rows parallel to each other with the Y-axis direction as the arrangement direction. In the example of FIG. 3, the pressure chamber substrate 10 is provided with two pressure chamber rows, that is, a first pressure chamber row L1 having a first arrangement direction parallel to the Y-axis direction and a second pressure chamber row L2 having a second arrangement direction parallel to the Y-axis direction. The first pressure chamber row L1 and the second pressure chamber row L2 are disposed on both sides with the wiring substrate 120 interposed therebetween. Specifically, the second pressure chamber row L2 is disposed on the opposite side of the first pressure chamber row L1 with the wiring substrate 120 interposed therebetween in the X-axis direction, which is the extending direction. In the example of FIG. 3, the second pressure chamber row L2 is disposed in the −X direction with the wiring substrate 120 interposed between the second pressure chamber row L2 and the first pressure chamber row L1. In the plurality of pressure chambers 12, all the pressure chambers 12 do not necessarily have to be arranged in a straight line, and for example, the plurality of pressure chambers 12 may be arranged in plurality along the Y-axis direction according to so-called staggered arrangement in which every other pressure chamber 12 is alternately disposed in an intersection direction.

As illustrated in FIG. 2, the communication plate 15, the nozzle plate 20, and the compliance substrate 45 are laminated on the +Z direction side of the pressure chamber substrate 10. The communication plate 15 is, for example, a flat plate member using a silicon substrate, a glass substrate, an SOI substrate, various ceramic substrates, a metal substrate, or the like. Examples of the metal substrate include a stainless steel substrate or the like. The communication plate 15 is provided with a nozzle communication path 16, a first manifold portion 17, a second manifold portion 18 illustrated in FIG. 4, and a supply communication path 19. It is preferable that the communication plate 15 is formed by using a material having a thermal expansion coefficient substantially the same as a thermal expansion coefficient of the pressure chamber substrate 10. As a result, when the temperatures of the pressure chamber substrate 10 and the communication plate 15 change, the warpage of the pressure chamber substrate 10 and the communication plate 15 due to a difference in the thermal expansion coefficients can be suppressed.

As illustrated in FIG. 4, the nozzle communication path 16 is a flow path that communicates the pressure chamber 12 and a nozzle 21. The first manifold portion 17 and the second manifold portion 18 function as a part of a manifold 100 which is a common liquid chamber in which the plurality of pressure chambers 12 communicate with each other. The first manifold portion 17 is provided to penetrate the communication plate 15 in the Z-axis direction. In addition, as illustrated in FIG. 4, the second manifold portion 18 is provided on a surface of the communication plate 15 on the +Z direction side without penetrating the communication plate 15 in the Z-axis direction.

As illustrated in FIG. 4, the supply communication path 19 is a flow path coupled to a pressure chamber supply path 14 provided on the pressure chamber substrate 10. The pressure chamber supply path 14 is a flow path coupled to one end portion of the pressure chamber 12 in the X-axis direction via a throttle portion 13. The throttle portion 13 is a flow path provided between the pressure chamber 12 and the pressure chamber supply path 14. The throttle portion 13 is a flow path in which an inner wall protrudes from the pressure chamber 12 and the pressure chamber supply path 14 and which is formed narrower than the pressure chamber 12 and the pressure chamber supply path 14. As a result, the throttle portion 13 is set such that the flow path resistance is higher than those of the pressure chamber 12 and the pressure chamber supply path 14. With the configuration, although pressure is applied to the pressure chamber 12 by the piezoelectric element 300 when the ink is discharged, the ink in the pressure chamber 12 can be suppressed or prevented from flowing back to the pressure chamber supply path 14. A plurality of supply communication paths 19 are arranged along the Y-axis direction, that is, the arrangement direction, and are individually provided for the respective pressure chambers 12. The supply communication path 19 and the pressure chamber supply path 14 communicate the second manifold portion 18 with each of the pressure chambers 12, and supply the ink in the manifold 100 to each of the pressure chambers 12.

The nozzle plate 20 is provided on a side opposite to the pressure chamber substrate 10, that is, on a surface of the communication plate 15 on the +Z direction side with the communication plate 15 interposed therebetween. The material of the nozzle plate 20 is not particularly limited, and for example, a silicon substrate, a glass substrate, an SOI substrate, various ceramic substrates, and a metal substrate can be used. Examples of the metal substrate include a stainless steel substrate or the like. As the material of the nozzle plate 20, an organic material, such as a polyimide resin, can also be used. However, it is preferable that the nozzle plate 20 uses a material having a thermal expansion coefficient substantially the same as a thermal expansion coefficient of the communication plate 15. As a result, when the temperatures of the nozzle plate 20 and the communication plate 15 change, the warpage of the nozzle plate 20 and the communication plate 15 due to a difference in the thermal expansion coefficients can be suppressed.

A plurality of nozzles 21 are provided on the nozzle plate 20. Each of the nozzles 21 communicates with each of the pressure chambers 12 via the nozzle communication path 16. As illustrated in FIG. 2, the plurality of nozzles 21 are arranged along the arrangement direction of the pressure chamber 12, that is, the Y-axis direction. The nozzle plate 20 is provided with two nozzle rows in which the plurality of nozzles 21 are arranged in a row. The two nozzle rows respectively correspond to the first pressure chamber row L1 and the second pressure chamber row L2.

As illustrated in FIG. 4, the compliance substrate 45 is provided together with the nozzle plate 20 on the side opposite to the pressure chamber substrate 10, that is, on a surface of the communication plate 15 on the +Z direction side with the communication plate 15 interposed therebetween. The compliance substrate 45 is provided around the nozzle plate 20 and covers openings of the first manifold portion 17 and the second manifold portion 18 provided in the communication plate 15. The compliance substrate 45 includes, for example, a sealing film 46 made of a flexible thin film and a fixed substrate 47 made of a hard material such as a metal. As illustrated in FIG. 4, a region of the fixed substrate 47 facing the manifold 100 is completely removed in a thickness direction, and thus an opening portion 48 is defined. Therefore, one surface of the manifold 100 is a compliance portion 49 sealed only by the sealing film 46.

As illustrated in FIG. 4, the vibration plate 50 and the piezoelectric element 300 are laminated on a side opposite to the communication plate 15 or the like, that is, on a surface of the pressure chamber substrate 10 on the −Z direction side with the pressure chamber substrate 10 interposed therebetween. The piezoelectric element 300 bends and deforms the vibration plate 50 to cause a pressure change in the ink in the pressure chamber 12. In FIG. 4, illustration of the piezoelectric element 300 is simplified.

The vibration plate 50 is provided between the piezoelectric element 300 and the pressure chamber substrate 10. The vibration plate 50 is provided at a position closer to the side of the pressure chamber substrate 10 than the piezoelectric element 300, and includes an elastic film 55 containing silicon oxide (SiO2) and an insulator film 56 that is provided on the elastic film 55 and contains a zirconium oxide film (ZrO2). The elastic film 55 composes a surface of the flow path, such as the pressure chamber 12, on the −Z direction side. In addition, the vibration plate 50 may be composed of, for example, either the elastic film 55 or the insulator film 56, and may further include another film other than the elastic film 55 and the insulator film 56. Examples of other film materials include silicon and silicon nitride.

As illustrated in FIG. 2, the sealing substrate 30 having substantially the same size as the pressure chamber substrate 10 in plan view is further bonded to a surface of the pressure chamber substrate 10 on the −Z direction side by an adhesive or the like. As illustrated in FIG. 4, the sealing substrate 30 includes a ceiling portion 30T, a wall portion 30W, a holding portion 31, and a through hole 32. The holding portion 31 is a space defined by the ceiling portion 30T and the wall portion 30W, and protects an active portion of the piezoelectric element 300 by accommodating the piezoelectric element 300. In the present embodiment, the holding portion 31 is provided for each row of the piezoelectric element 300, and more specifically, the two holding portions 31 corresponding to the first pressure chamber row L1 and the second pressure chamber row L2 are formed to be adjacent to each other. The through hole 32 penetrates the sealing substrate 30 along the Z-axis direction. The through hole 32 is disposed between the two holding portions 31 in plan view, and is formed in a long rectangular shape along the Y-axis direction.

As illustrated in FIG. 4, the case member 40 is fixed on the sealing substrate 30. The case member 40 forms the manifold 100 that communicates with the plurality of pressure chambers 12, together with the communication plate 15. The case member 40 has substantially the same outer shape as the communication plate 15 in plan view, and is bonded to cover the sealing substrate 30 and the communication plate 15.

The case member 40 has an accommodation section 41, a supply port 44, a third manifold portion 42, and a coupling port 43. The accommodation section 41 is a space having a depth in which the pressure chamber substrate 10, the vibration plate 50, and the sealing substrate 30 can be accommodated. The third manifold portion 42 is a space provided in the vicinity of both ends of the accommodation section 41 in the X-axis direction in the case member 40. The manifold 100 is formed by coupling the third manifold portion 42 to the first manifold portion 17 and the second manifold portion 18 provided in the communication plate 15. The manifold 100 has a long shape in the Y-axis direction. The supply port 44 communicates with the manifold 100 to supply ink to each manifold 100. The coupling port 43 is a through hole that communicates with the through hole 32 of the sealing substrate 30, and the wiring substrate 120 is inserted thereto.

In the liquid discharge head 510, the ink supplied from the ink tank 550 illustrated in FIG. 1 is taken from the supply port 44 illustrated in FIG. 4, an internal flow path from the manifold 100 to the nozzle 21 is filled with ink, and then a voltage based on the drive signal is applied to each of the piezoelectric elements 300 corresponding to the plurality of pressure chambers 12. As a result, the vibration plate 50 bends and deforms together with the piezoelectric element 300, so that the volume of each of the pressure chambers 12 changes to increase the internal pressure, and ink droplets are discharged from each of the nozzles 21.

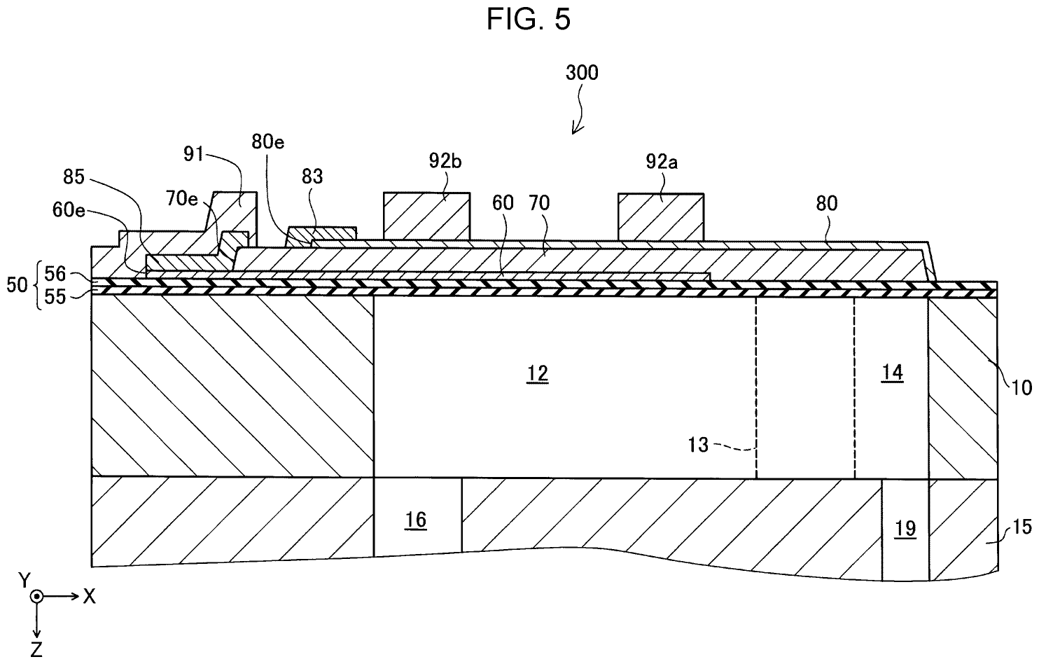

The configuration of the piezoelectric element 300 will be described with reference to FIGS. 3 and 4 and FIG. 5 as appropriate. FIG. 5 is a cross-sectional view schematically illustrating the detailed configuration of the piezoelectric element 300.

As illustrated in FIG. 5, the piezoelectric element 300 has a first electrode 60, a piezoelectric body 70, and a second electrode 80. The first electrode 60, the piezoelectric body 70, and the second electrode 80 are laminated in this order in the −Z direction of the lamination direction. The piezoelectric body 70 is provided between the first electrode 60 and the second electrode 80 in the lamination direction. The first electrode 60 is provided on the +Z direction side of the piezoelectric body 70, and the second electrode 80 is provided on the −Z direction side of the piezoelectric body 70.

The first electrode 60 and the second electrode 80 are electrically coupled to the wiring substrate 120 illustrated in FIGS. 3 and 4 via a drive wiring. The drive wiring includes a first drive wiring 91 that electrically couples the wiring substrate 120 and the first electrode 60, and a second drive wiring 92 that electrically couples the wiring substrate 120 and the second electrode 80. The first electrode 60 and the second electrode 80 apply a voltage corresponding to the drive signal to the piezoelectric body 70. The drive voltage is a voltage applied to the piezoelectric element 300 from the first electrode 60 and the second electrode 80 to drive the piezoelectric element 300 by the controller 580. In the piezoelectric element 300, the first electrode 60 and the second electrode 80 are respectively provided in the +Z direction of the piezoelectric body 70 and in the −Z direction thereof, and when a voltage is applied between the first electrode 60 and the second electrode 80, a portion in which piezoelectric strain occurs in the piezoelectric body 70 is also referred to as an active portion. In addition, in the piezoelectric element 300, the first electrode 60 is not provided in the +Z direction of the piezoelectric body 70, and a portion in which piezoelectric strain does not occur in the piezoelectric body 70 although a voltage is applied between the first electrode 60 and the second electrode 80 is also referred to as a non-active portion.

A different drive voltage is applied to the first electrode 60 according to a discharge amount of ink, and a predetermined reference voltage is applied to the second electrode 80 regardless of the discharge amount of ink. When a voltage difference is generated between the first electrode 60 and the second electrode 80 by applying the drive voltage and the reference voltage, the piezoelectric body 70 of the piezoelectric element 300 is deformed. Due to the deformation of the piezoelectric body 70, the vibration plate 50 is deformed or vibrated, so that the volume of the pressure chamber 12 changes. Due to the change in the volume of the pressure chamber 12, pressure is imparted to the ink accommodated in the pressure chamber 12, and the ink is discharged from the nozzle 21 via the nozzle communication path 16.

In the present embodiment, the first electrode 60 is an individual electrode individually provided for the plurality of pressure chambers 12. As illustrated in FIG. 5, the first electrode 60 is a lower electrode provided on the opposite side to the second electrode 80, that is, on the lower side of the piezoelectric body 70 with the piezoelectric body 70 interposed therebetween. The thickness of the first electrode 60 is formed to be, for example, approximately 80 nanometers. For example, the first electrode 60 is formed of a conductive material including a metal, such as platinum (Pt), iridium (Ir), gold (Au), titanium (Ti), and a conductive metal oxide such as indium tin oxide abbreviated as ITO. The first electrode 60 may be formed by laminating a plurality of materials such as platinum (Pt), iridium (Ir), gold (Au), and titanium (Ti). In the present embodiment, platinum (Pt) is used as the first electrode 60.

As illustrated in FIG. 3, the piezoelectric body 70 has a predetermined width in the X-axis direction, and has a long rectangular shape along the arrangement direction of the pressure chambers 12, that is, the Y-axis direction. In the present embodiment, the piezoelectric body 70 is formed as a thin film having a thickness of 5 μm or less. Examples of the piezoelectric body 70 include a crystal film having a perovskite structure provided on the first electrode 60 and made of a ferroelectric ceramic material exhibiting an electromechanical conversion action, that is, a so-called perovskite type crystal. In the present embodiment, the piezoelectric body 70 is made of a composite oxide containing potassium, sodium, and niobium, more specifically, potassium sodium niobate ((K, Na) (NbO3), abbreviated as “KNN”). As described above, the liquid discharge head 510 of the present embodiment includes the non-lead-based piezoelectric body 70. The liquid discharge head 510 including the non-lead-based piezoelectric body 70 according to the present embodiment is configured such that the content of lead contained in the liquid discharge head 510 is 0.1% by weight or less (preferably, does not contain lead at all). A more detailed structure of the piezoelectric body 70 will be described later. The material of the piezoelectric body 70 is not limited to the above material, and may be configured by, for example, bismuth ferrite ((BiFeO3), abbreviated to “BFO”), barium titanate ((BaTiO3), abbreviated to “BT”), potassium sodium lithium niobate ((K, Na, Li) (NbO3)), potassium sodium lithium tantalate niobate ((K, Na, Li) (Nb, Ta)O3), bismuth potassium titanate ((Bi1/2K1/2)TiO3, abbreviated to “BKT”), bismuth sodium titanate ((Bi1/2Na1/2)TiO3, abbreviated to “BNT”), bismuth manganese (BiMnO3, abbreviated to “BM”), a composite oxide containing bismuth, potassium, titanium, and iron and having a perovskite structure (x[(BixK1-x)TiO3]-(1-x)[BiFeO3], abbreviated to “BKT-BF”), a composite oxide containing bismuth, iron, barium, and titanium and having a perovskite structure ((1-x)[BiFeO3]-x[BaTiO3], abbreviated to “BFO-BT”), or one to which a metal such as manganese, cobalt, or chromium is added ((1-x)[Bi(Fe1-yMy)O3]-x[BaTiO3] (M is Mn, Co, or Cr)), or the like.

As illustrated in FIG. 3, the second electrode 80 is a common electrode that is commonly provided for the plurality of pressure chambers 12. The second electrode 80 has a predetermined width in the X-axis direction, and is provided to extend along the arrangement direction of the pressure chambers 12, that is, the Y-axis direction. As illustrated in FIG. 5, the second electrode 80 is an upper electrode provided on the opposite side to the first electrode 60, that is, on the upper side of the piezoelectric body 70 with the piezoelectric body 70 interposed therebetween. As a material of the second electrode 80, similar to the first electrode 60, for example, a conductive material including a metal, such as platinum (Pt), iridium (Ir), gold (Au), and titanium (Ti), and a conductive metal oxide, such as indium tin oxide abbreviated as ITO, is used. In the present embodiment, iridium (Ir) is used as the second electrode 80.

As illustrated in FIG. 5, the protective layer 83 is formed at an end portion 80e of the second electrode 80 on the −X direction side. The protective layer 83 is made of an organic material such as polyimide (aromatic polyimide) or an inorganic material such as aluminum oxide (Al2O3).

As illustrated in FIG. 5, a wiring portion 85 is provided on the −X direction side rather than the end portion 80e of the second electrode 80 in the −X direction. In FIG. 3, the wiring portion 85 is not illustrated. The wiring portion 85 is in the same layer as the second electrode 80, but is electrically discontinuous with the second electrode 80. The wiring portion 85 is formed from an end portion 70e of the piezoelectric body 70 in the −X direction to an end portion 60e of the first electrode 60 in the −X direction in a state where an interval is provided from the end portion 80e of the second electrode 80. The end portion 60e of the first electrode 60 in the −X direction is drawn out to the outside from the end portion 70e of the piezoelectric body 70. The wiring portion 85 is provided for each of the piezoelectric elements 300, and are disposed in plurality at a predetermined interval along the Y-axis direction. It is preferable that the wiring portion 85 is formed in the same layer as the second electrode 80. As a result, the manufacturing step of the wiring portion 85 can be simplified, so that the cost can be reduced. However, the wiring portion 85 may be formed in a layer different from the layer of the second electrode 80.

As illustrated in FIG. 5, the first drive wiring 91 is electrically coupled to the first electrode 60 which is an individual electrode, and an extension portion 92a and extension portion 92b of the second drive wiring 92 are electrically coupled to the second electrode 80 which is a common electrode. The first drive wiring 91 and the second drive wiring 92 function as drive wirings for applying a voltage for driving the piezoelectric body 70 from the wiring substrate 120.

The first drive wiring 91 is individually provided for each of the first electrodes 60. As illustrated in FIG. 5, the first drive wiring 91 is coupled to the vicinity of the end portion 60e of the first electrode 60 via the wiring portion 85, and is drawn out in the −X direction to reach a top of the vibration plate 50. The first drive wiring 91 is electrically coupled to the end portion 60e of the first electrode 60 in the −X direction drawn out to the outside from the end portion 70e of the piezoelectric body 70. The wiring portion 85 may be omitted, and the first drive wiring 91 may be directly coupled to the end portion 60e of the first electrode 60.

As illustrated in FIG. 3, the second drive wiring 92 extends along the Y-axis direction, bends at both ends in the Y-axis direction, and is drawn out along the X-axis direction. The second drive wiring 92 includes the extension portion 92a and the extension portion 92b extending along the Y-axis direction. As illustrated in FIG. 3 and FIG. 4, the end portions of the first drive wiring 91 and the second drive wiring 92 are extended to be exposed to the through hole 32 of the sealing substrate 30, and are electrically coupled to the wiring substrate 120 in the through hole 32.

The materials of the first drive wiring 91 and the second drive wiring 92 are conductive materials, and for example, gold (Au), copper (Cu), titanium (Ti), tungsten (W), nickel (Ni), chromium (Cr), platinum (Pt), aluminum (Al), or the like can be used. In the present embodiment, gold (Au) is used for the first drive wiring 91 and the second drive wiring 92. In the present embodiment, the first drive wiring 91 and the second drive wiring 92 are formed by sputtering. The first drive wiring 91 and the second drive wiring 92 are not limited to the sputtering and may be formed by any known film forming technique.

The first drive wiring 91 and the second drive wiring 92 are formed in the same layer in a state of being electrically discontinuous with each other. As a result, the step of forming the first drive wiring 91 and the step of forming the second drive wiring 92 can be shared, and, as compared with the case where the first drive wiring 91 and the second drive wiring 92 are individually formed, the manufacturing step can be simplified, so that the decrease in productivity of the liquid discharge head 510 can be suppressed. Here, the first drive wiring 91 and the second drive wiring 92 may be formed in different layers from each other. The first drive wiring 91 and the second drive wiring 92 may have an adhesion layer that improves adhesion to the first electrode 60, the second electrode 80, or the vibration plate 50.

The wiring substrate 120 is composed of, for example, a flexible printed circuit (FPC). The wiring substrate 120 is formed with a plurality of wirings for being coupled to the controller 580 and a power supply circuit (not illustrated). In addition, any flexible substrate, such as flexible flat cable (FFC), instead of FPC may be used. An integrated circuit 121 including a switching element or the like is mounted at the wiring substrate 120. A command signal or the like for driving the piezoelectric element 300 is input to the integrated circuit 121. The integrated circuit 121 controls a timing at which a drive signal for driving the piezoelectric element 300 is supplied to the first electrode 60 based on the command signal.

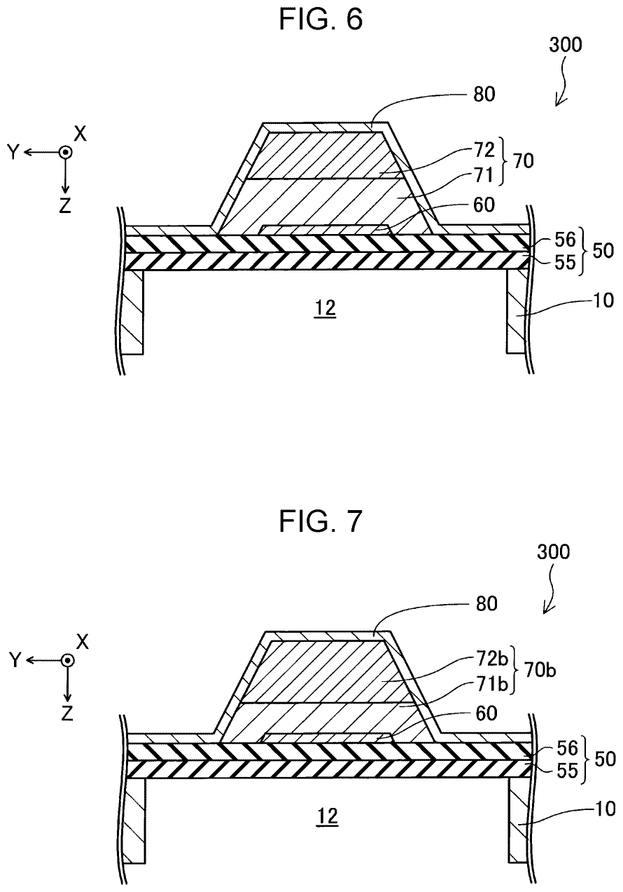

FIG. 6 is a cross-sectional view schematically illustrating a detailed configuration of the piezoelectric body 70. FIG. 6 illustrates a part of a cross section at a position VI-VI of FIG. 3. In the present embodiment, the piezoelectric body 70 has a first thin film piezoelectric body 71 and a second thin film piezoelectric body 72. As illustrated in FIG. 6, the pressure chamber substrate 10, the vibration plate 50, the first electrode 60, the first thin film piezoelectric body 71, the second thin film piezoelectric body 72, and the second electrode 80 are laminated in this order in the −Z direction, which is the lamination direction.

In the present embodiment, the first thin film piezoelectric body 71 is first laminated by a sol-gel method, and the second thin film piezoelectric body 72 is laminated on first thin film piezoelectric body 71 by a sol-gel method. The second thin film piezoelectric body 72, for example, is formed to have a higher density than the first thin film piezoelectric body 71, so that the Young's modulus of the second thin film piezoelectric body 72 can be made higher than the Young's modulus of the first thin film piezoelectric body 71. The first thin film piezoelectric body 71 and the second thin film piezoelectric body 72 are directly laminated without interposing other members therebetween. In the present embodiment, the film formation of the thin film piezoelectric body is divided into two stages to adjust the Young's moduli of the first thin film piezoelectric body 71 and the second thin film piezoelectric body 72 as described above. After the first electrode 60 is formed and patterned on the vibration plate 50, the precursor solution of the first thin film piezoelectric body 71 is applied and fired to crystallize the first thin film piezoelectric body 71. Thereafter, the precursor solution of the second thin film piezoelectric body 72 is separately applied and fired, and the second thin film piezoelectric body 72 is crystallized on the first thin film piezoelectric body 71. Thereafter, the first thin film piezoelectric body 71 and the second thin film piezoelectric body 72 are patterned, and the second electrode 80 is formed. The firing times and firing temperatures of the first thin film piezoelectric body 71 and the second thin film piezoelectric body 72, the type and concentration of the precursor solution, the coating amount, or the like are appropriately changed, so that the Young's moduli of the first thin film piezoelectric body 71 and the second thin film piezoelectric body 72 can be controlled. For example, when the precursor solutions of the first thin film piezoelectric body 71 and the second thin film piezoelectric body 72 contain elements different from the main constituent element of each thin film piezoelectric body, it is known that the Young's modulus increases. When the KNN is used as the first thin film piezoelectric body 71 and the second thin film piezoelectric body 72, each precursor solution naturally contains K, Na, and Nb, but when the precursor solution of the second thin film piezoelectric body 72 contains more amounts of an element such as Mn than the precursor solution of the first thin film piezoelectric body 71, the second thin film piezoelectric body 72 can have a higher Young's modulus than the first thin film piezoelectric body 71. In addition, it is also known that the higher the firing temperature, the more likely the Young's modulus is to increase. Therefore, although the precursor solutions are the same for the first thin film piezoelectric body 71 and the second thin film piezoelectric body 72, the precursor solution of the first thin film piezoelectric body 71 can be made to have a relatively low firing temperature of approximately 630° C., and the precursor solution of the second thin film piezoelectric body 72 can be made to have a relatively high firing temperature of approximately 670° C., so that the second thin film piezoelectric body 72 can have a higher Young's modulus than the first thin film piezoelectric body 71. Here, an example of a method of controlling the Young's moduli of the first thin film piezoelectric body 71 and the second thin film piezoelectric body 72 is described, but it is needless to say that the Young's moduli may be controlled by other methods.

The reason why the piezoelectric body 70 of the present embodiment is composed as described above will be described. Generally, since the non-lead-based piezoelectric body 70 has a larger tensile stress than the lead-based piezoelectric body 70, a stress difference between the non-lead-based piezoelectric body 70 and the vibration plate 50 is to increase, so that a crack may occur. To suppress the occurrence of such cracks, the attempt of the inventors is made to reduce the Young's modulus of the piezoelectric body, in other words, to soften the piezoelectric body. As a result, the stress difference between the piezoelectric body and the vibration plate can be alleviated, and the occurrence of cracks can be suppressed.

However, in general, the driving force by the piezoelectric body depends on the product of the piezoelectric constant of the piezoelectric body, the Young's modulus of the piezoelectric body, and the thickness of the piezoelectric body, so that, when the Young's modulus of the entire piezoelectric body is decreased, the driving force by the piezoelectric body is reduced. Therefore, the attempt of the inventors is made to form the piezoelectric body 70 into a laminated structure of a plurality of layers of the first thin film piezoelectric body 71 and the second thin film piezoelectric body 72 as in the present embodiment, and to set the Young's modulus of the second thin film piezoelectric body 72, which is positioned farther from the vibration plate 50, to be larger than the Young's modulus of the first thin film piezoelectric body 71, which is positioned closer to the vibration plate 50, between the first thin film piezoelectric body 71 and the second thin film piezoelectric body 72.

The vibration plate 50 is deformed in tension by the piezoelectric body 70 being deformed in compression. At this time, it can be said that the force point is positioned on the side of the piezoelectric body 70 and the action point is positioned on the side of the vibration plate 50. In addition, the fulcrum is a neutral axis of the piezoelectric element 300 and the vibration plate 50. The neutral axis referred to here is a position at which the compressive stress and the tensile stress of the piezoelectric element 300 and the vibration plate 50 are balanced. In the present embodiment, the neutral axis is positioned slightly closer to the +Z direction side than the vicinity of the contact portion between the piezoelectric body 70 and the vibration plate 50. As can be understood from considering the moment of force, the position farther from the neutral axis, that is, the deformation of the piezoelectric body 70 in the −Z direction side contributes greatly to the displacement of the vibration plate 50. That is, when the Young's modulus of the second thin film piezoelectric body 72 is made to be larger than the Young's modulus of the first thin film piezoelectric body 71, the displacement of the vibration plate 50 can be increased, and the displacement characteristic of the entire piezoelectric body 70 can be improved. On the other hand, Young's modulus of the first thin film piezoelectric body 71 in contact with the vibration plate 50 is made to be smaller than the Young's modulus of the second thin film piezoelectric body 72, so that the occurrence of cracks is suppressed. As described above, according to the piezoelectric body 70 of the present embodiment, the occurrence of cracks can be suppressed as the displacement characteristic is improved.

In addition, in the present embodiment, the Young's modulus of the second thin film piezoelectric body 72 is configured to be 1.3 times to 2.1 times the Young's modulus of the first thin film piezoelectric body 71. It is more desirable that the Young's modulus of the second thin film piezoelectric body 72 is 1.5 times to 1.9 times the Young's modulus of the first thin film piezoelectric body 71. A member having a low Young's modulus is formed to have a low density and thus has a low electrical resistance. On the other hand, a member having a high Young's modulus is formed to have a high density and has a high electrical resistance. That is, when a voltage is applied to the piezoelectric body configured by laminating members having different Young's moduli, most of a withstand voltage is handled by the member having a large Young's modulus and a large electrical resistance, and the balance of the withstand voltage between the two laminated members is broken, and there is a concern that the piezoelectric body is damaged. The ratio of the Young's modulus of the second thin film piezoelectric body 72 with respect to the Young's modulus of the first thin film piezoelectric body 71 is set as the above-described range, so that the breakdown of the balance of the withstand voltage between the first thin film piezoelectric body 71 and the second thin film piezoelectric body 72 can be suppressed, and the damage to the piezoelectric body 70 can be suppressed.

According to the liquid discharge head 510 of the first embodiment described above, the Young's modulus of the second thin film piezoelectric body 72 is larger than the Young's modulus of the first thin film piezoelectric body 71, so that the displacement characteristic of the piezoelectric body 70 can be improved. In addition, since the Young's modulus of the first thin film piezoelectric body 71 is smaller than the Young's modulus of the second thin film piezoelectric body 72, the stress difference between the piezoelectric body 70 and the vibration plate 50 can be alleviated, and the occurrence of cracks can be suppressed. That is, the occurrence of cracks can be suppressed as the displacement characteristic is improved.

In addition, since the Young's modulus of the second thin film piezoelectric body 72 is 1.3 times to 2.1 times the Young's modulus of the first thin film piezoelectric body 71, the breakdown of the balance of the withstand voltage between the first thin film piezoelectric body 71 and the second thin film piezoelectric body 72 can be suppressed, and the damage to the piezoelectric body 70 can be suppressed.

### B. Second Embodiment

FIG. 7 is a cross-sectional view schematically illustrating a detailed configuration of a piezoelectric body 70b of a second embodiment. The configuration of each portion of the liquid discharge head 510 other than the piezoelectric body 70b in the second embodiment is the same as that of the first embodiment.

As illustrated in FIG. 7, the piezoelectric body 70b of the second embodiment is configured such that the second thin film piezoelectric body 72b is thicker than the first thin film piezoelectric body 71b. As described above, the driving force by the piezoelectric body depends on the product of the piezoelectric constant of the piezoelectric body, the Young's modulus of the piezoelectric body, and the thickness of the piezoelectric body. Therefore, the second thin film piezoelectric body 72b is made to be thicker than the first thin film piezoelectric body 71b, so that the displacement characteristic of the second thin film piezoelectric body 72b positioned on the −Z direction side in which the contribution to the displacement of the vibration plate 50 is larger can be further improved, and the displacement characteristic of the piezoelectric body 70b can be further improved.

In addition, in the present embodiment, the thickness of the second thin film piezoelectric body 72b is configured to be 1.5 times to 2.5 times the thickness of the first thin film piezoelectric body 71b. When the ratio of the thickness of the second thin film piezoelectric body 72b with respect to the thickness of the first thin film piezoelectric body 71b is increased, the thickness of the piezoelectric body 70b is to be excessively large, and there is a concern that the power required for driving the piezoelectric body 70b increases and the manufacturing cost of the liquid discharge head 510 increases. The ratio of the thickness of the second thin film piezoelectric body 72b with respect to the thickness of the first thin film piezoelectric body 71b is made to be in the above-described range, so that such increase in power and increase in manufacturing cost can be suppressed.

According to the liquid discharge head 510 including the piezoelectric body 70b of the second embodiment described above, since the second thin film piezoelectric body 72b is thicker than the first thin film piezoelectric body 71b, the decrease in the displacement characteristic of the second thin film piezoelectric body 72b positioned on the −Z direction side in which the contribution to the displacement of the vibration plate 50 is larger can be further improved, and the displacement characteristic of the piezoelectric body 70 can be further improved.

In addition, since the thickness of the second thin film piezoelectric body 72b is 1.5 times to 2.5 times the thickness of the first thin film piezoelectric body 71b, the thickness of the piezoelectric body 70b can be suppressed from being excessively large, and the increase in the power required for driving the piezoelectric body 70b and the increase in the manufacturing cost can be suppressed.

### C. Third Embodiment

The piezoelectric body 70 of the third embodiment is different from the piezoelectric body 70 of the first embodiment in that the piezoelectric constant of the second thin film piezoelectric body 72 is larger than the piezoelectric constant of the first thin film piezoelectric body 71. As described above, the driving force by the piezoelectric body depends on the product of the piezoelectric constant of the piezoelectric body, the Young's modulus of the piezoelectric body, and the thickness of the piezoelectric body. Therefore, according to the liquid discharge head 510 including the piezoelectric body 70 of the present embodiment, the piezoelectric constant of the second thin film piezoelectric body 72 is made to be larger than the piezoelectric constant of the first thin film piezoelectric body 71, so that the displacement characteristic of the second thin film piezoelectric body 72 positioned on the −Z direction side in which the contribution to the displacement of the vibration plate 50 is larger can be made higher, and the displacement characteristic of the piezoelectric body 70 can be further improved.

In addition, in the present embodiment, the piezoelectric constant of the second thin film piezoelectric body 72 is configured to be 1.1 times to 1.3 times the piezoelectric constant of the first thin film piezoelectric body 71. Therefore, the piezoelectric body 70 can be suppressed from being damaged when the difference in the displacement characteristics between the first thin film piezoelectric body 71 and the second thin film piezoelectric body 72 is excessively large.

According to the liquid discharge head 510 including the piezoelectric body 70 of the third embodiment described above, since the piezoelectric constant of the second thin film piezoelectric body 72 is higher than the piezoelectric constant of the first thin film piezoelectric body 71, the displacement characteristic of the second thin film piezoelectric body 72 positioned on the −Z direction side in which the contribution to the displacement of the vibration plate 50 is larger can be further improved, and the displacement characteristic of the piezoelectric body 70 can be further improved.

In addition, since the piezoelectric constant of the second thin film piezoelectric body 72 is 1.1 times to 1.3 times the piezoelectric constant of the first thin film piezoelectric body 71, the piezoelectric body 70 can be suppressed from being damaged when the difference in the displacement characteristics between the first thin film piezoelectric body 71 and the second thin film piezoelectric body 72 is excessively large.

### D. Other Embodiments

(D1) In the above embodiment, the piezoelectric body 70 is composed of two layers of the first thin film piezoelectric body 71 and the second thin film piezoelectric body 72, but the present disclosure is not limited thereto. The piezoelectric body 70 may be composed of a plurality of layers, three or more. In such an aspect, among the plurality of layers, the Young's modulus of the layer positioned further in the −Z direction is configured to be higher than the Young's modulus of the layer positioned further in the +Z direction. The same effect as that of the above embodiment can also be obtained by the above-described aspect.

(D2) In the above embodiment, the first thin film piezoelectric body 71 and the second thin film piezoelectric body 72 are laminated by the sol-gel method, but the present disclosure is not limited thereto. The first thin film piezoelectric body 71 and the second thin film piezoelectric body 72 may be laminated by any known film forming technique, for example, sputtering. The same effect as that of the above embodiment can also be obtained by the above-described aspect.

### E. Other Aspects

The present disclosure is not limited to the above-described embodiments, and can be realized in various configurations without departing from the gist of the present disclosure. For example, technical features in the embodiments corresponding to technical features in each aspect to be described below can be replaced or combined as appropriate to solve some or all of the problems described above, or to achieve some or all of the effects described above. In addition, unless the technical features are described as essential in the present specification, deletion is possible as appropriate.
(1) According to a first aspect of the present disclosure, there is provided a liquid discharge head. The liquid discharge head includes a pressure chamber substrate provided with a plurality of pressure chambers, a vibration plate, a first electrode, a first thin film piezoelectric body, a second thin film piezoelectric body, and a second electrode, which are laminated in this order along a lamination direction, in which a content of lead contained in the liquid discharge head is 0.1% by weight or less, no other member is interposed between the first thin film piezoelectric body and the second thin film piezoelectric body, and a Young's modulus of the second thin film piezoelectric body is higher than a Young's modulus of the first thin film piezoelectric body. According to the aspect, since the Young's modulus of the second thin film piezoelectric body is higher than the Young's modulus of the first thin film piezoelectric body, the decrease in the displacement characteristic of the second thin film piezoelectric body positioned farther from the vibration plate in the lamination direction in which the contribution to the displacement of the vibration plate is larger can be suppressed, and the decrease in the displacement characteristic of the piezoelectric body can be suppressed. In addition, since the Young's modulus of the first thin film piezoelectric body is smaller than the Young's modulus of the second thin film piezoelectric body 72, the stress difference between the piezoelectric body and the vibration plate can be alleviated, and the occurrence of cracks can be suppressed. That is, the occurrence of cracks can be suppressed as the displacement characteristic is improved.
(2) In the above aspect, the Young's modulus of the second thin film piezoelectric body may be 1.3 times to 2.1 times the Young's modulus of the first thin film piezoelectric body. According to the aspect, the breakdown of the balance of the withstand voltage between the first thin film piezoelectric body and the second thin film piezoelectric body can be suppressed, and the damage to the piezoelectric body can be suppressed.
(3) In the above aspect, the Young's modulus of the second thin film piezoelectric body may be 1.5 times to 1.9 times the Young's modulus of the first thin film piezoelectric body. According to the aspect, the breakdown of the balance of the withstand voltage between the first thin film piezoelectric body and the second thin film piezoelectric body can be further suppressed, and the damage of the piezoelectric body can be further suppressed.
(4) In the above aspect, the second thin film piezoelectric body may be thicker than the first thin film piezoelectric body. According to the aspect, since the second thin film piezoelectric body is thicker than the first thin film piezoelectric body, the displacement characteristic of the second thin film piezoelectric body positioned farther from the vibration plate in the lamination direction in which the contribution to the displacement of the vibration plate is larger can be further improved, and the displacement characteristic of the piezoelectric body can be further improved.
(5) In the above aspect, a thickness of the second thin film piezoelectric body may be 1.5 times to 2.5 times a thickness of the first thin film piezoelectric body. According to the aspect, the thickness of the piezoelectric body can be suppressed from being excessively large, and the increase in power required for driving the piezoelectric body and the increase in manufacturing cost can be suppressed.
(6) In the above aspect, a piezoelectric constant of the second thin film piezoelectric body may be larger than a piezoelectric constant of the first thin film piezoelectric body. According to the aspect, the displacement characteristic of the second thin film piezoelectric body positioned farther from the vibration plate in the lamination direction in which the contribution to the displacement of the vibration plate is larger can be further improved, and the displacement characteristic of the piezoelectric body can be further improved.
(7) In the above aspect, the piezoelectric constant of the second thin film piezoelectric body may be 1.1 times to 1.3 times the piezoelectric constant of the first thin film piezoelectric body. According to the aspect, the piezoelectric body can be suppressed from being damaged when the difference in the displacement characteristics between the first thin film piezoelectric body and the second thin film piezoelectric body is excessively large.
(8) In the above aspect, the first thin film piezoelectric body and the second thin film piezoelectric body may be formed of a composite oxide containing potassium, sodium, and niobium. According to the aspect, in the liquid discharge head including the first thin film piezoelectric body and the second thin film piezoelectric body formed from a composite oxide containing potassium, sodium, and niobium, both the suppression of the decrease of the displacement characteristic of the piezoelectric body and the suppression of the occurrence of cracks can be achieved.
(9) According to a second aspect of the present disclosure, there is provided a liquid discharge device. The liquid discharge device includes the liquid discharge head according to any one of aspects 1 to 8, and a controller that controls a discharge operation from the liquid discharge head. According to the aspect, in the liquid discharge device, the occurrence of cracks can be suppressed as the displacement characteristic of the piezoelectric body included in the liquid discharge head is improved. The suppression can be made.

The present disclosure can also be realized in various aspects other than the liquid discharge device and the liquid discharge head. For example, the present disclosure with an aspect of a method for manufacturing a liquid discharge head, a method for manufacturing a liquid discharge device, or the like can be realized.

The present disclosure is not limited to the ink jet method, and can be applied to any liquid discharge device that discharges a liquid other than the ink and a liquid discharge head that is used for the liquid discharge device. For example, the present disclosure can be applied to the following various liquid discharge devices and liquid discharge heads thereof.
(1) An image recording device such as a facsimile device.
(2) A color material discharge device used for manufacturing a color filter for an image display device such as a liquid crystal display.
(3) An electrode material discharge device used for
forming electrodes of an organic electro luminescence (EL) display, a field emission display (FED), or the like.
(4) A liquid discharge device that discharges a liquid containing a bioorganic material used for manufacturing a biochip.
(5) A sample discharge device as a precision pipette.
(6) A lubricating oil discharge device.
(7) A resin liquid discharge device.
(8) A liquid discharge device that discharges lubricating oil with pinpoint to a precision machine such as a watch or a camera.
(9) A liquid discharge device that discharges a transparent resin liquid, such as an ultraviolet curable resin liquid, onto a substrate to form a micro hemispherical lens (optical lens) or the like used for an optical communication element or the like.
(10) A liquid discharge device that discharges an acidic or alkaline etching liquid for etching a substrate or the like.
(11) A liquid discharge device including a liquid consumption head that discharges any other minute amount of liquid droplets.

Further, the “liquid” may be any material that can be consumed by the liquid discharge device. For example, the “liquid” may be a material in a state when a substance is liquefied, and the “liquid” includes a liquid state material with high or low viscosity and a liquid state material, such as a sol, gel water, other inorganic solvent, organic solvent, solution, liquid resin, and liquid metal (metal melt). In addition, the “liquid” includes not only a liquid as a state of a substance but also a liquid in which particles of a functional material made of a solid substance, such as a pigment or a metal particle, are dissolved, dispersed, or mixed in a solvent, or the like. In addition, the following is mentioned as a typical example of a liquid.
(1) Adhesive main agent and curing agent.
(2) Paint-based paints and diluents, clear paints and diluents.
(3) Main solvent and diluting solvent containing cells of ink for cells.
(4) Metallic leaf pigment dispersion liquid and diluting solvent of ink (metallic ink) that develops metallic luster.
(5) Gasoline/diesel and biofuel for vehicle fuel.
(6) Main ingredients and protective ingredients of medicine.
(7) Light emitting diode (LED) fluorescent material and encapsulant.

Furthermore, the present invention is not limited to piezoelectric element for liquid discharge head, but can be applied to piezoelectric elements in general for other uses, such as speakers, ultrasonic motors, various sensors such as angle sensors and acceleration sensors, ferroelectric memories, and ferroelectric capacitors.

What is claimed is:

1. A liquid discharge head comprising:
a pressure chamber substrate provided with a plurality of pressure chambers;
a vibration plate;
a first electrode;
a first thin film piezoelectric body;
a second thin film piezoelectric body; and
a second electrode, which are laminated in this order along a lamination direction, wherein
a content of lead contained in the liquid discharge head is 0.1% by weight or less,
no other member is interposed between the first thin film piezoelectric body and the second thin film piezoelectric body, and
a Young's modulus of the second thin film piezoelectric body is higher than a Young's modulus of the first thin film piezoelectric body.

2. The liquid discharge head according to claim 1, wherein
the Young's modulus of the second thin film piezoelectric body is 1.3 times to 2.1 times the Young's modulus of the first thin film piezoelectric body.

3. The liquid discharge head according to claim 2, wherein
the Young's modulus of the second thin film piezoelectric body is 1.5 times to 1.9 times the Young's modulus of the first thin film piezoelectric body.

4. The liquid discharge head according to claim 1, wherein
the second thin film piezoelectric body is thicker than the first thin film piezoelectric body.

5. The liquid discharge head according to claim 4, wherein
a thickness of the second thin film piezoelectric body is 1.5 times to 2.5 times a thickness of the first thin film piezoelectric body.

6. The liquid discharge head according to claim 1, wherein
a piezoelectric constant of the second thin film piezoelectric body is larger than a piezoelectric constant of the first thin film piezoelectric body.

7. The liquid discharge head according to claim 6, wherein
the piezoelectric constant of the second thin film piezoelectric body is 1.1 times to 1.3 times the piezoelectric constant of the first thin film piezoelectric body.

8. The liquid discharge head according to claim 1, wherein
the first thin film piezoelectric body and the second thin film piezoelectric body are formed of a composite oxide containing potassium, sodium, and niobium.

9. A liquid discharge device comprising:
the liquid discharge head according to claim 1; and
a controller that controls a discharge operation from the liquid discharge head.

10. A piezoelectric element comprising:
a first electrode;
a first thin film piezoelectric body;
a second thin film piezoelectric body; and
a second electrode, which are laminated in this order along a lamination direction, wherein
the first thin film piezoelectric body and the second thin film piezoelectric body are formed of a composite oxide containing potassium, sodium, and niobium,
a Young's modulus of the second thin film piezoelectric body is higher than a Young's modulus of the first thin film piezoelectric body.

11. The piezoelectric element according to claim 10, wherein
no other member is interposed between the first thin film piezoelectric body and the second thin film piezoelectric body.

12. The piezoelectric element according to claim 10, wherein
the Young's modulus of the second thin film piezoelectric body is 1.3 times to 2.1 times the Young's modulus of the first thin film piezoelectric body.

13. The piezoelectric element according to claim 12, wherein
the Young's modulus of the second thin film piezoelectric body is 1.5 times to 1.9 times the Young's modulus of the first thin film piezoelectric body.

14. The piezoelectric element according to claim 10, wherein
the second thin film piezoelectric body is thicker than the first thin film piezoelectric body.

15. The piezoelectric element according to claim 14, wherein
a thickness of the second thin film piezoelectric body is 1.5 times to 2.5 times a thickness of the first thin film piezoelectric body.

16. The piezoelectric element according to claim 10, wherein
a piezoelectric constant of the second thin film piezoelectric body is larger than a piezoelectric constant of the first thin film piezoelectric body.

17. The piezoelectric element according to claim 16, wherein
the piezoelectric constant of the second thin film piezoelectric body is 1.1 times to 1.3 times the piezoelectric constant of the first thin film piezoelectric body.
